(19) United States
(12) Patent Application Publication
(10) Pub. No.: US 2011/0180393 A1
(43) Pub. Date: Jul. 28, 2011

(54) PROCESS FOR FORMING A BACK REFLECTOR FOR PHOTOVOLTAIC DEVICES

(76) Inventors: Shafiul A. Chowdhury, Albuguergue, NM (US); Richard J. Podlesny, Perrysburg, OH (US); Xinmin Cao, Sylvania, OH (US); Ramasamy Raju, Sylvania, OH (US)

(21) Appl. No.: 13/010,871

(22) Filed: Jan. 21, 2011

Related U.S. Application Data
(60) Provisional application No. 61/298,090, filed on Jan. 25, 2010.

(51) Int. Cl. C23C 14/35; C23C 14/06

(52) U.S. Cl. 204/192.27

(57) ABSTRACT

A process for forming a textured back reflector for a photovoltaic device is provided. The process includes providing a moving substrate, positioning the substrate within a deposition chamber, and sputtering a metal or a metal alloy target positioned within the deposition chamber to produce sputtered material. The process further includes introducing a reacting gas mixed with argon into the deposition chamber. The reacting gas and the sputtered metal or metal alloy material form an alloy layer. The alloy layer is formed on the substrate and provides a textured surface on the substrate.

### RELATED APPLICATION

This application is claiming the benefit, under 35 U.S.C. 119(e), of the provisional application which was granted Ser. No. 61/298,090 filed on Jan. 25, 2010, the disclosure of which is hereby entirely incorporated by reference.

### BACKGROUND OF THE INVENTION

This invention relates generally to thin-film photovoltaic (PV) devices, and more specifically to an improved process for forming a back reflector that has a high texture and a high reflectivity for use in thin-film PV devices. More particularly, the invention provides a process for forming an improved back reflector and allows for greater control of the back reflector texture and reflectivity.

Thin-film PV devices which can be produced by forming thin-film PV semiconductor materials, such as thin-film silicon based amorphous silicon (a-Si), on low-cost substrates such as glass, stainless steel, etc, have been intensively studied and developed in recent years.

FIG. 1 illustrates an a-Si based thin-film PV device 10 known in the art made on a metal substrate 12. The metal substrate 12 is covered with a conventional back reflector 14. The back reflector 14 includes a metallic layer 16 covered with a transparent and conductive oxide (TCO) barrier layer 18. An a-Si based semiconductor material 20 and a front contact TCO layer 22 are next disposed atop the back reflector 14.

The back reflector 14 is generally applied underneath the semiconductor material 20 to improve the performance of the device 10. In this arrangement, the back reflector 14 reflects the portion of sunlight that has passed through but has not been absorbed yet, back into the semiconductor material 20 for further absorption. The back reflector 14 may also utilize a metallic layer having a high texture for better light scattering and trapping.

In order to reduce the cost of manufacturing a PV device and the light induced degradation of the PV device, semiconductor material absorber layers of the PV device must not be thick. On the other hand, a thin absorber layer will not cost-effectively produce energy from the sun. Therefore, one way to improve the performance of a PV device is to increase the diffuse reflection (increase scattering) from the back reflector. Diffuse reflectivity results in very high absorption of the light due to the enhanced internal reflection. However, depositing a highly textured back reflector and controlling the texture is problematic.

Therefore, a need exists for a method of producing and controlling the deposition of a highly textured back reflector in a PV device.

### BRIEF SUMMARY OF THE INVENTION

A process for forming a textured back reflector for a photovoltaic device is provided.

In an embodiment, the process comprises providing a moving substrate. The process comprises positioning the substrate within a deposition chamber. The process also comprises sputtering a metal or a metal alloy target positioned within the deposition chamber to produce sputtered material. Further, the process comprises introducing a reacting gas mixed with argon gas into the deposition chamber. The reacting gas and the sputtered metal or metal alloy material form an alloy layer. The alloy layer is formed on the substrate and provides a textured surface on the substrate.

In another embodiment, the process for forming a textured back reflector for a photovoltaic device comprises providing a stainless steel substrate at approximately 400° C. The process also comprises providing a deposition chamber. The substrate is moving at rate of between 5 and 100 inches per minute within the chamber. Further, the process comprises providing a metal target comprising aluminum and sputtering the metal target to produce sputtered material. A reacting gas is continuously introduced into the deposition chamber to react with the sputtered material. An alloy layer is formed on the substrate by the reaction of the reacting gas and the sputtered material. The alloy layer has an RMS surface roughness of at least 60 nm and a diffuse reflection of at least 38%.

### BRIEF DESCRIPTION OF THE DRAWINGS

FIG. 1 is a PV device known in the art;

FIG. 2 is a PV device of the present invention;

FIG. 3 is a cross-sectional view of an embodiment of the present invention;

FIG. 4 is a graph of diffuse reflectance versus portions of the electromagnetic spectrum;

FIG. 5a is an AFM image of a metal alloy layer made by an embodiment of the present invention;

FIG. 5b is an AFM image of a metal alloy layer made by an embodiment of the present invention;

FIG. 5c is an AFM image of a metal alloy layer made by an embodiment of the present invention;

FIG. 5d is an AFM image of a metal alloy layer made by an embodiment of the present invention;

FIG. 6 is a graph of diffuse reflectance versus portions of the electromagnetic spectrum for Examples 5-7 of Table 2;

FIG. 7 is a graph of total reflectance versus portions of the electromagnetic spectrum for Examples 5-7 of Table 2;

FIG. 8a is an AFM image of a metal alloy layer made by an embodiment of the present invention;

FIG. 8b is an AFM image of a metal alloy layer made by an embodiment of the present invention;

FIG. 8c is an AFM image of a metal alloy layer made by an embodiment of the present invention; and

FIG. 9 is a graph depicting diffuse reflectance versus O₂/argon gas mixture flow rates for Examples 8-10 of Table 3.

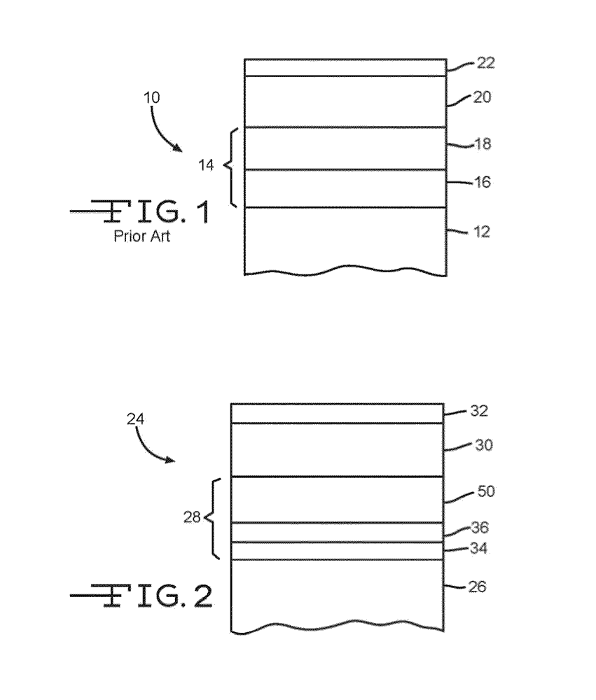

### DETAILED DESCRIPTION OF THE INVENTION

It is to be understood that the invention may assume various alternative orientations and step sequences, except where expressly stated to the contrary. It should also be appreciated that the specific embodiments and processes illustrated in and described in the following specification are simply exemplary embodiments of the inventive concepts defined in the appended claims. For example, although the present invention will be described in connection with a-Si the present invention is not so limited. As such, the present invention may also be applied to PV devices having at least one single junction (SJ) of cadmium telluride (CdTe) single junction (SJ), amorphous silicon germanium (a-SiGe), crystalline silicon (c-Si), microcrystalline silicon (mc-Si), nanocrystalline silicon (nc-Si), Copper indium sulphide (CIS₂), or Copper Indium Gallium (di)Selenide (CIGS). Additionally, although the present invention will be described with a substrate it should be appreciated that it may also be utilized in connection with a superstrate.

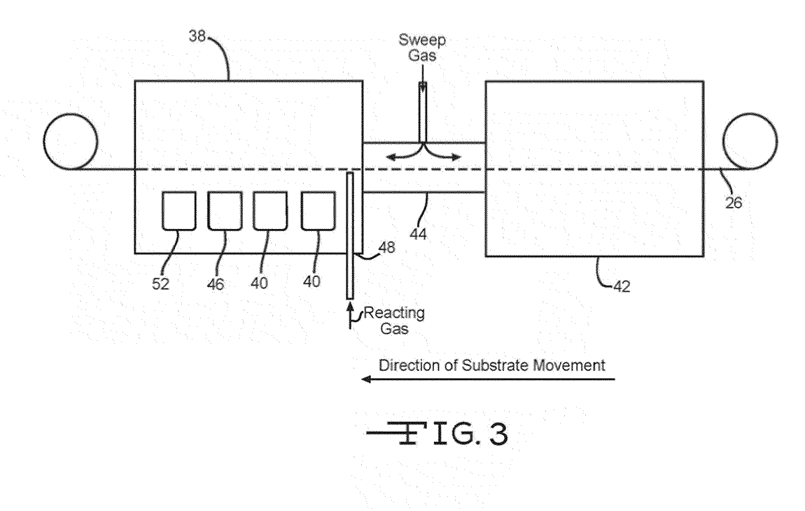

FIG. 2 illustrates a state of the art a-Si based thin film PV device 24 formed on a substrate 26 coated with a textured back reflector 28 with high diffuse reflection. In an embodiment, the PV device 24 comprises a substrate 26, for an electric back contact and device support, a textured back reflector 28, a-Si based PV semiconductor material(s) 30 and a front contact TCO layer 32. In an embodiment, the substrate is metallic and is preferably a foil of stainless steel. In another embodiment, the PV device 24 comprises a polymeric substrate instead of a metallic substrate.

The textured back reflector 28 is deposited over the substrate 26 and provides a textured and conductive surface thereon. The textured back reflector 28 is preferably deposited directly on the substrate 26. The textured back reflector 28 comprises an alloy layer 34. The alloy layer 34 is preferably a metal alloy layer. In an embodiment, the textured back reflector 28 further comprises a light reflecting layer 36 deposited over the metal alloy layer 34, i.e. on the side of the metal alloy layer 34 spaced apart from the substrate 26.

The light reflecting layer 36 comprises at least one material which has a visible light reflectivity which is higher than the metal alloy layer 34. Preferably, the visible light reflectivity of the light reflecting layer 36 is ≧90%. In an embodiment, the light reflecting layer 36 is selected from the group of aluminum, silver, copper, palladium, and combinations thereof. In this embodiment, the metal alloy layer 34 and the light reflecting layer 36 provide a combined benefit which allows the textured back reflector 28 to produce higher total and diffuse reflection.

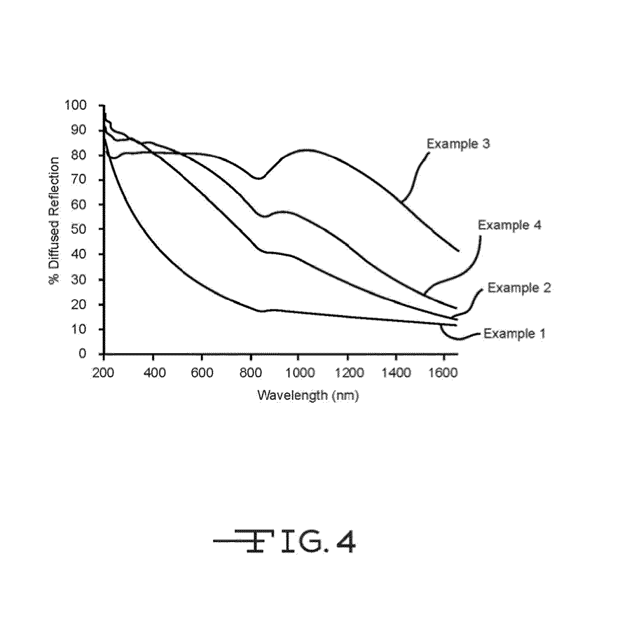

The textured back reflector 28 can be formed from a process for deposition thin films. As shown in FIG. 3, the process for forming the textured back reflector 28 comprises providing the substrate 26 and positioning the substrate 26 within a deposition chamber 38.

In an embodiment, the thin film deposition process is sputtering, preferably magnetron sputtering. In this embodiment, the sputtering process may be performed at a low pressure. For instance, depositing the metal alloy layer 34 is done at a pressure of approximately 2-20 militorr in the deposition chamber 38. Preferably, the pressure in the deposition chamber 38 is from about 3 to about 15 militorr. However, it should be appreciated that other thin film deposition methods may be utilized in forming the PV device 24 including for depositing the textured back reflector 28.

The deposition chamber 38 has an inert atmosphere, preferably argon (Ar), and is maintained at a temperature of between approximately 100° C. to 500° C., preferably between approximately 100° C. to 430° C., and more preferably at a temperature of approximately 400° C. Thus, the substrate 26 may also be at a temperature of between approximately 100° C. to 500° C. and preferably at a temperature of approximately 400° C. Also, positioned within the deposition chamber 38 is at least one metal or metal alloy sputtering target 40 for use as material for forming the metal alloy layer 34. In an embodiment, the metal or metal alloy sputtering target(s) 40 comprises aluminum. In this embodiment, the metal or metal alloy sputtering target(s) 40 may be substantially pure aluminum or an alloy of aluminum, preferably an Al—Si alloy. However, the other materials, such as silver, may be used with or substituted for aluminum in depositing the metal alloy layer 34.

As stated above, the process for forming the textured back reflector 28 comprises providing the substrate 26. In an embodiment, the substrate 26 is moving as the textured back reflector 28 is being deposited. In this embodiment, the substrate 26 may be moved as part of roll-to-roll process for forming thin film PV devices. Preferably, the substrate 26 is moving at a rate of at least 6 inch per minute. In an embodiment, the substrate 26 is moving at a rate of between 5 inches per minute and 100 inches per minute. Preferably, the substrate 26 is moving at a rate of between 24 inches per minute and 60 inches per minute.

Before entering the deposition chamber 38, it is preferred that any surface contamination on the surface of the substrate 26 where the PV device 24 will be formed is removed. As shown in FIG. 3, this can be done by providing a cleaning chamber 42 upstream of the deposition chamber 38 which uses a gas mixture of Ar and oxygen (O₂) to clean the substrate 26. The cleaning chamber 42 is preferably in fluid communication with the deposition chamber 38. A bridge chamber 44 may be provided between the cleaning chamber 42 and the deposition chamber 38 to prevent the gas flow from the cleaning chamber 42 from entering the deposition chamber 38. Typically, a sweep gas is introduced into the bridge chamber 44 to prevent the cleaning chamber gases (O₂, H₂O etc.) and the deposition chamber gases from mixing.

Within the deposition chamber 38, forming the metal alloy layer 34 may be initiated by creating a plasma of ionized Ar atoms. The ionized Ar atoms continuously strike the metal or metal alloy target to produce sputtered material. In an embodiment where at least one metal or metal alloy sputtering target 40 is positioned within the deposition chamber 38, the sputtered material is ejected from the target surface in the direction of the substrate deposition surface where the metal alloy layer 34 is deposited. The light reflecting layer 36 may be formed in a similar manner utilizing a sputtering target 46 or targets comprising the desired light reflecting layer material.

The process for forming the textured back reflector 28 also comprises introducing a reacting gas into the deposition chamber 38. The reacting gas and the sputtered material react to form the metal alloy layer 34. The reacting gas is preferably introduced into the deposition chamber 38 with Ar gas as a reacting gas/Ar gas mixture. In an embodiment, the reacting gas is an oxidizing gas. In another embodiment, the reacting gas contains O and OH atoms and ions. In these embodiments, the reacting gas may comprise water vapor (H₂O), O₂, or a combination thereof. In a further embodiment, the reacting gas is selected from the group consisting of O₂, H₂O and Nitrogen (N₂).

As noted above, since the substrate 26 is moving in and through the deposition chamber 38, the reacting gas must be continuously introduced into the deposition chamber 38. Depending on the desired texture of the back reflector 28, the reacting gas may be introduced into deposition chamber 38 at a fixed flow rate or a variable flow rate. As depicted in FIG. 3, in an embodiment the reacting gas may be introduced directly into the deposition chamber 38. In this embodiment, the reacting gas is preferably introduced into the deposition chamber 38 in a uniform manner across the width of the substrate 26. However, in an embodiment, the reacting gas may be introduced into the cleaning chamber 42 and allowed to pass across the bridge chamber 44 to be introduced into the deposition chamber 38. In another embodiment, the reacting gas may be introduced into the bridge chamber 44 or the bridge chamber sweep gas and, from there, introduced into the deposition chamber 38.

Referring back to FIG. 2, in an embodiment the textured back reflector 28 comprises the metal alloy layer 34 and light reflecting layer 36. Back reflector texture is mainly provided by the metal alloy layer texture. The metal alloy layer texture is also responsible for light scattering or diffuse reflection. The texture of the metal alloy layer 34 can be controlled by target material choice and the flow rate of the reacting gas. Thus, preferably the reacting gas is introduced into the deposition chamber 38 with a controlled flow. In this embodiment, a mass flow controller may be utilized. The amount and/or concentration of reacting gas within the deposition chamber may also monitored by a residual gas analyzer (RGA). Controlling of the texture of the back reflector 28 can thus be accomplished by monitoring and maintaining the concentration of reacting gas within the deposition chamber 38 and increasing and/or decreasing the reacting gas flow to achieve a desired texture.

In an embodiment, the metal alloy layer 34 and the light reflecting layer 36 are deposited in the same deposition chamber 38. In this embodiment, the reacting gas does not substantially react with the sputter material used to form the light reflecting layer 36. Preventing the reacting gas from substantially reacting with the material used to form the light reflecting layer 36 may be achieved in several ways. In an embodiment, the materials used to form the light reflecting layer 36 are selected so that the light reflecting layer will not undergo an appreciable change when exposed to the reacting gas and will continue to reflect visible light and minimize scatter loss. In another embodiment, the deposition chamber 38 may be partitioned to inhibit the flow of the reacting gas into the section of the deposition chamber 38 where the light reflecting layer 36 is formed. In yet another embodiment, the reacting gas is introduced in a portion 48 of the deposition chamber 38 adjacent the at least one metal or metal alloy target 40. This portion 48 of the deposition chamber 38 may also be adjacent the location where the substrate 26 enters the deposition chamber 38.

Interdiffusion between the a-Si semiconductor material 30 and the metal alloy layer 34 and the light reflecting layer 36 can happen when the semiconductor material 30 is directly deposited on the metal alloy layer 34 or the light reflecting layer 36. Therefore, as indicated in FIG. 2, the textured back reflector 28 may further comprise a barrier layer 50 may be deposited between the a-Si semiconductor material 30 and the metal alloy layer 34 or the light reflecting layer 36 to prevent such interdiffusion, i.e. on the side of the metal alloy layer 34 or the light reflecting layer 36 spaced apart from the substrate 26. The barrier layer 50 is preferably formed utilizing the sputtering process, described above, and preferably with a sputtering target 52 or targets comprising the desired barrier layer material.

The barrier layer 50 is preferably a TCO barrier layer. In an embodiment, the TCO barrier layer 50 comprises zinc oxide or aluminum doped zinc oxide. The TCO may be deposited at thickness of 100-2000 nanometers (nm), preferably at a thickness of 300 nm. However, it should be appreciated that other barrier layer materials may be used in practicing the present invention.

### Examples

The following examples are presented solely for the purpose of further illustrating and disclosing the present invention, and are not to be construed as a limitation on, the invention.

The following experimental conditions are applicable to Examples 1-10 unless otherwise indicated.

A deposition chamber having a cathode, a metal target of substantially pure aluminum, and magnetron sputtering capability were provided. The deposition chamber had an Ar atmosphere and was maintain at a pressure of approximately 6 militorr.

A 36-inch wide stainless steel substrate was moved within the deposition chamber and heated to approximately 430° C. For examples 1-3, the substrate was moved in and through the deposition chamber at a rate of 6 inches per minute. For examples 1-3, the power to the aluminum cathode was approximately 14 KW and the aluminum metal alloy layer was deposited at a thickness of approximately 300 nm. For Example 4, the substrate was moved in and through the deposition chamber at a rate of 8 inches per minute and the power to the aluminum cathode was approximately 18.1 KW and the aluminum metal alloy layer was deposited at a thickness of approximately 300 nm.

For Examples 5-7, the substrate was moved in and through the deposition chamber at a rate of 18 inches per minute. Also, for Examples 5-7, the power to the aluminum cathode was approximately 39 KW and the aluminum metal alloy layer was deposited at a thickness of approximately 300 nm. For examples 8-10, the substrate was moved in and through the deposition chamber at a rate of 12 inches per minute, the power to the aluminum cathode was approximately 18 KW, and the aluminum metal alloy layer was deposited at a thickness approximately 300 nm.

For Examples 1-10, the stainless steel substrate was positioned above the cathode and the metal target in the deposition chamber.

A sputter deposition process was initiated by creating plasma of ionized Ar atoms. The aluminum metal target was continually struck with ionized Ar atoms. The sputtered aluminum was ejected from the target surface in the direction of the substrate surface.

Before entering the deposition chamber, the substrate was moved through a cleaning chamber to remove surface contamination. The cleaning chamber is in fluid communication with the deposition chamber. As stated above and shown in FIG. 3, the cleaning chamber may be connected to the deposition chamber by a bridge chamber and a sweep gas is introduced into the bridge chamber to prevent the cleaning chamber gases and the deposition chamber gases from mixing. In Example 1-4, oxygen as an 80/20 Ar/O₂ mix was continuously introduced into the cleaning chamber. In Example 1, the sweep gas flow rate was 180 sccm of Ar. In Example 2, the sweep gas flow rate was 90 sccm of Ar. In Example 3, the sweep gas flow rate was 45 sccm of Ar. In Example 4, the sweep gas flow rate was 45 sccm of Ar. By decreasing the sweep gas flow rate into the bridge chamber, the reacting gas, for example O₂ and/or H₂O, flow rate into the deposition chamber can be increased and varied.

In Examples 5-7, reacting gas was H₂O (water vapor) and it was directly introduced into the deposition chamber adjacent the location where the substrate enters the deposition chamber. The flow rate of the reacting gas was controlled with a mass flow controller. The water vapor pressure was monitored via an RGA connected to the deposition chamber. The H₂O vapor pressure was varied between 4.1 E-5 Torr to 7.4 E-5 Torr. In Example 8-10, the reacting gas was an O₂/Ar and they were introduced where the substrate enters of the deposition chamber. The flow rate of the reacting gas was controlled with a mass flow controller. The flow was varied between 3 and 10 sccm.

The sputtered materials, the reacting gas, the deposition conditions described above allow an alloy layer to form on the surface of the substrate which, as Table 1, Table 2 and Table 3 summarize, provides a back reflector with improved surface roughness and diffuse reflection.

TABLE 1
Aluminum metal alloy layer deposited on a stainless steel substrate

| | | | | | Flow rate |
|---|---|---|---|---|---|
| | Surface | | | | of 80/20 |
| | Roughness | Diffuse | Diffuse | Diffuse | argon/ |
| | in RMS | reflectivity | reflectivity | reflectivity | oxygen |
| Example | (nm) | at 600 nm | at 800 nm | at 1000 nm | mixture |
| 1 | 44 | 28% | 18% | 17% | 20 |
| 2 | 64 | 38% | 55% | 38% | 40 |
| 3 | 107.6 | 80% | 72% | 82% | 40 |
| 4 | 70 | 76% | 59% | 56% | 40 |

RMS: root-mean-square roughness

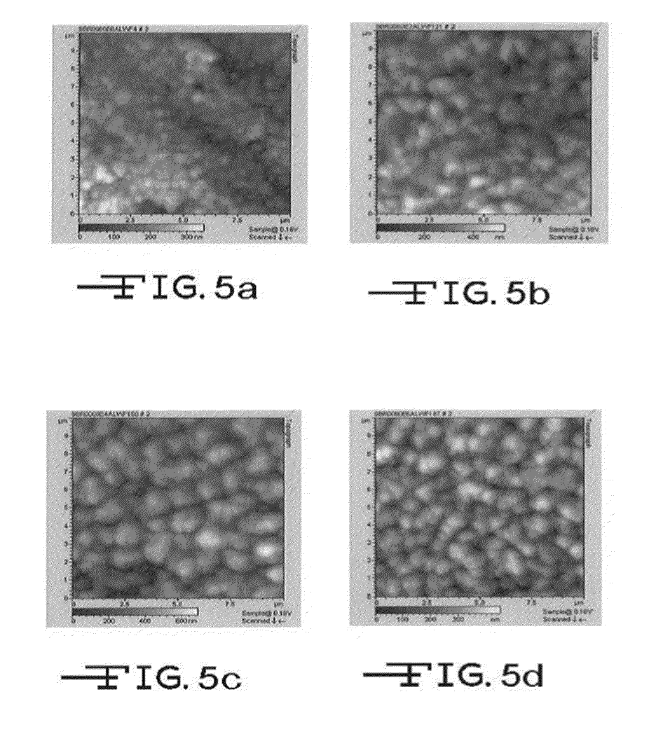

In Example 1, none of the oxygen from the Ar/O₂ mixture introduced into the cleaning chamber entered the deposition chamber. However, by increasing the flow rate of the Ar/O₂ mixture and lowering the sweep gas flow rate, the amount of O₂ entering the deposition chamber was increased. As illustrated in Table 1, as the flow rate of the Ar/O₂ mixture was increased and flow rate of sweep gas was decreased, the diffuse reflection increased. As shown in FIG. 4 and Table 1, the diffuse reflection of the aluminum alloy layer was increased by approximately 55 percentage points as measured at 1000 nm of the electromagnetic spectrum.

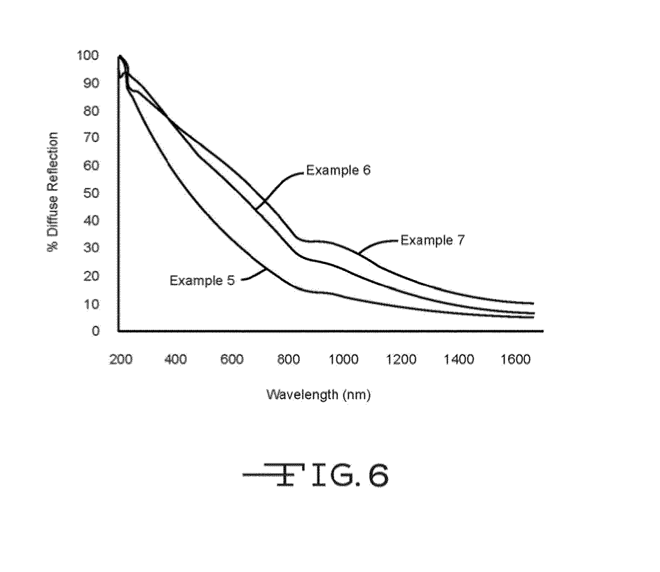

The conditions of Examples 2-4, shown in FIGS. 5b-5d, produce a textured back reflector with larger crystalline grain sizes then the grain size that was produced by the conditions of Example 1, shown in FIG. 5a. Additionally, the textured back reflector of Example 2-4 comprises a metal alloy layer of aluminum and O₂. The metal alloy layer provides a texture surface on the substrate which reflects visible wavelengths of light and provides improved visible light scattering.

TABLE 2
Aluminum metal alloy layer deposited on a stainless steel substrate

| | | Diffuse | Total |
|---|---|---|---|
| | RGA H₂0 vapor | reflectivity at | reflectivity |
| Example | pressure (Torr) | 830 nm | at 830 nm |
| 5 | 4.1E−5 | 15.8% | 80.5% |
| 6 | 5.1E−5 | 27.8% | 76.2% |
| 7 | 7.4E−5 | 35.2% | 73.3% |

TABLE 3
Aluminum metal alloy layer deposited on a stainless steel substrate

| | | Diffuse | Total |
|---|---|---|---|
| | O₂/Ar flow rate | reflectivity at | reflectivity |
| Example | (sccm) | 830 nm | at 830 nm |
| 8 | 3 | 42% | 67.3% |
| 9 | 6 | 42.2% | 64% |
| 10 | 10 | 45.1% | 62% |

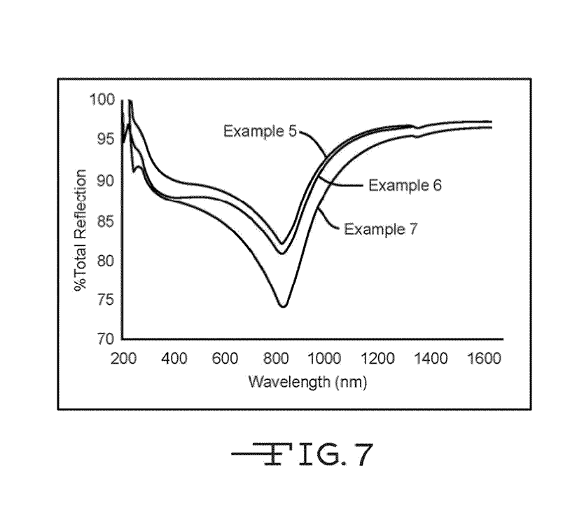

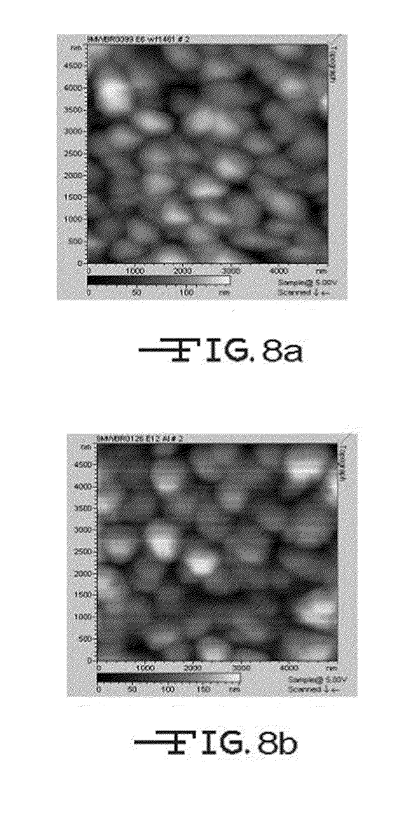

In Example 5-7 water vapor was introduced in the deposition chamber adjacent the location where the substrate enters the chamber. The H₂O vapor pressure was varied and measured by an RGA attached to the deposition chamber. H₂O vapor pressure measured by the RGA for Examples 5, 6 and 7 was 4.1 E-5 Torr, 5.1 E-5 Torr, and 7.4 E-5 Torr, respectively. Table 2 and FIG. 6 and FIG. 7 depict the effect of water vapor on the reflectivity of the textured back reflector. As shown, increases of H₂O content in the metal alloy layer increased the diffuse reflectivity of aluminum metal alloy layer from 15% to 35%.

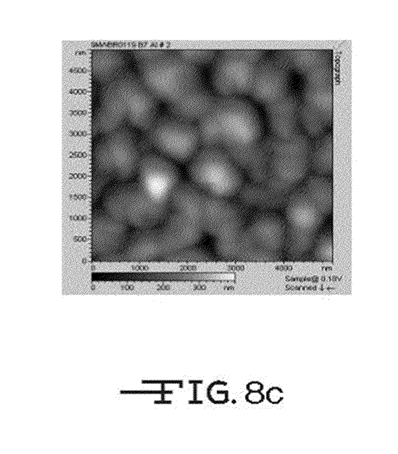

FIGS. 8a-8c show AFM images of metal alloy layers produced with the different H₂O content in the deposition chamber. The metal alloy layer shown in FIG. 8a has an RMS surface roughness of 24 nm and was formed with a lower H₂O vapor pressure in the deposition chamber than the metal alloy layer shown in FIG. 8b. The metal alloy layer shown in FIG. 8b has an RMS surface roughness of 30 nm and was formed with a lower H₂O vapor pressure in the deposition chamber than the metal alloy layer shown in FIG. 8c. The metal alloy layer shown in FIG. 8c has an RMS surface roughness of 65 nm. Thus, as shown, increasing of H₂O vapor pressure in the deposition chamber results in a metal alloy layer that is formed with more textured and eventually an RMS surface roughness that increases with the increase in H₂O vapor pressure.

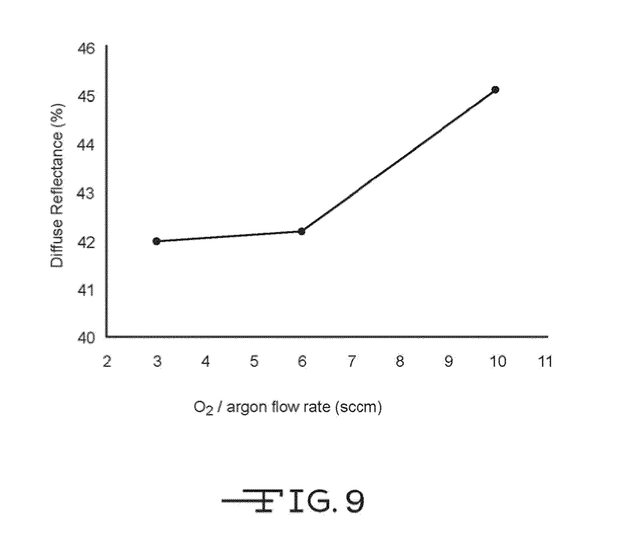

In Examples 8-10 oxygen was added in the deposition chamber adjacent the location where the substrate enters the chamber. The O₂/Ar mixture flow rate was varied from 3 sccm to 10 sccm. Table 3 and FIG. 9 show the effect of O₂ in the reflectivity of textured back reflector. As shown, increasing the O₂/Ar mixture flow rate in the deposition chamber increases the diffuse reflectivity of metal alloy layer.

The above detailed description of the present invention is given for explanatory purposes. Thus, it will be apparent to those skilled in the art that numerous changes and modification can be made without departing from the scope of the invention.

Accordingly, the whole of the foregoing description is to be constructed in an illustrative and not a limitative sense. Therefore, specific dimensions, directions or other physical characteristics relating to the embodiments disclosed are not to be considered as limiting, unless the claims expressly state otherwise.

What is claimed is:

1. A process for forming a textured back reflector for a photovoltaic device, comprising:
providing a moving substrate;
positioning the substrate within a deposition chamber;
sputtering a metal or a metal alloy target positioned within the deposition chamber to produce sputtered material; and
introducing a reacting gas mixed with argon gas into the deposition chamber, wherein the reacting gas and the sputtered metal or metal alloy material form an alloy layer, the alloy layer is formed on the substrate and provides a textured surface on the substrate.

2. The process of claim 1, wherein the reacting gas contains O and OH atoms.

3. The process of claim 1, wherein the substrate is a stainless steel foil.

4. The process of claim 1, wherein the substrate is moving at a rate of at least 6 inches per minute.

5. The process of claim 1, wherein the substrate is at a temperature from about 100° C. to about 500° C.

6. The process of claim 1, wherein the deposition chamber is at a pressure from about 3 millitorr to about 15 millitorr.

7. The process of claim 1, wherein the alloy layer is conductive.

8. The process of claim 1, further comprising controlling alloy layer texture by continuously introducing an amount of reacting gas into the deposition chamber.

9. The process of claim 1, wherein the reacting gas is introduced into the deposition chamber in a uniform manner across a width of the substrate.

10. The process of claim 1, wherein the reacting gas is introduced into the deposition chamber at a fixed flow rate.

11. The process of claim 1, wherein the reacting gas is introduced into the deposition chamber at a variable flow rate.

12. The process of claim 1, wherein the reacting gas is selected from the group consisting of O₂, H₂O, and N₂.

13. The process of claim 1, wherein the metal or metal alloy target comprises an alloy of aluminum or is substantially pure aluminum.

14. The process of claim 1, further comprising depositing a light reflecting layer on the side of the alloy layer spaced apart from the substrate.

15. The process of claim 1, further comprising depositing a barrier layer on the side of the alloy layer spaced apart from the substrate.

16. The process of claim 1, wherein the alloy layer has an RMS surface roughness of at least 60 nm and has a thickness of approximately 200 nm.

17. The process of claim 1, further comprising controlling alloy layer texture by maintaining a concentration of reacting gas in the deposition chamber.

18. The process of claim 16, wherein the barrier layer comprises zinc oxide or aluminum doped zinc oxide.

19. A process for forming a textured back reflector for a photovoltaic device, comprising:
providing a stainless steel substrate at approximately 400° C.;
providing a deposition chamber, wherein the substrate is moving at rate of between 5 and 100 inches per minute within the chamber;
providing a metal target comprising aluminum;
sputtering the metal target to produce sputtered material;
continuously introducing a reacting gas into the deposition chamber to react with the sputtered material; and
forming an alloy layer on the substrate by the reaction of the reacting gas and the sputtered material, wherein the alloy layer has an RMS surface roughness of at least 60 nm and a diffuse reflection of at least 38%.

20. The process of claim 22, further comprising forming a light reflecting layer over the alloy layer to provide a total visible light reflection of above 75% and a diffuse reflection of between 18-35%.
